(19) United States
(12) Patent Application Publication
(10) Pub. No.: US 2024/0339354 A1
(43) Pub. Date: Oct. 10, 2024

(54) SPACER DEVICE FOR A HEATING SYSTEM FOR HEATING LARGE-AREA SUBSTRATES, HEATING SYSTEM, AND HEATING METHOD

(71) Applicant: SINGULUS TECHNOLOGIES AG, Kahl am Main (DE)

(72) Inventors: Sergiy BORODIN, Aschaffenburg (DE); Andreas LUDWIG, Aschaffenburg (DE)

(21) Appl. No.: 18/294,883

(22) PCT Filed: Jul. 15, 2022
(86) PCT No.: PCT/EP2022/069865

§ 371 Date: Feb. 2, 2024

(30) Foreign Application Priority Data
Aug. 13, 2021 (DE) 10 2021 004 175.5

(51) Int. Cl. H01L 21/687; H01L 21/67

(52) U.S. Cl. CPC H01L 21/68785; H01L 21/67098

(57) ABSTRACT

the present invention relates to a spacer device for a heating system for heating large-area substrates, a heating system for heating large-area substrates, and a method for heating large-area substrates.

The present invention relates to a spacer device for a heating system for heating large-area substrates, a heating system for heating large-area substrates, as well as to a method for heating large-area substrates.

For various processes, e.g., with respect to thin-film photovoltaics, it is necessary to heat large-area substrates with dimensions of, e.g., 1.5 m×2 μm to temperatures of, e.g., 700° C. The increased temperature may reduce the stability of the substrate, which occurs particularly with the use of glass when its softening point is exceeded. Thus, it is necessary for the substrate to be fully or partially supported by a carrier plate during the heating process. In the simplest case, the substrate is usually placed on a heating plate that is directly or indirectly heated. However, for instance, slight unevenness of the substrate may lead to locally varying contact between the substrate and the heating plate, which affects the heating process and results in considerable temperature inhomogeneities in the substrate. Said local differences in temperature may have a detrimental effect on the substrate or result in destruction of the same due to thermal stress. These problems occur more frequently in particular when substrates with poor thermal conductivity (for instance, glass) are heated very quickly, e.g., at rates of 5 K/s.

) In order to take this problem into account, DE 199 36 081 A1 suggests heating by means of a so-called transparent body that comprises a specific transmission and a specific absorption for the relevant electromagnetic radiation. In this way, the substrate is to be heated partly directly by electromagnetic radiation which passes through the transparent body and partly indirectly by thermal conduction through contact with the transparent body which heats by means of absorption. The transparent body may comprise a spacer against which the substrate rests. This type of heating, however, is disadvantageous in that, among other things, it is difficult to control precisely. A complete temperature equality between the substrate to be heated and the transparent carrier body, however, can only be achieved if close tolerances are adhered to. For instance, this equilibrium is already disturbed by a change in the thickness ratios or the absorption capacity of the substrate. Such a change in the absorption capacity takes place, e.g., by adding reflecting or highly absorbent layers to the substrate. Therefore, there is a need for heating systems for large-area substrates which allow for higher differences in temperature between the carrier and the substrate, too.

It is thus an object of the present invention to provide an improved heating system, i.e., an improved method for heating large-area substrates, which overcomes the disadvantages of the prior art. In particular, it is also an object of the present invention to provide an improved spacer device for a heating system for heating large-area substrates by means of which substrates of this kind may be positioned at a defined distance from, e.g., a susceptor plate in an easy and cost-effective manner.

These objects are achieved by the features of the independent claims. Preferred embodiments are claimed, inter alia, in the dependent claims.

Consequently, according to the first aspect, the present invention provides a spacer device for a heating system for heating large-area substrates. The spacer device comprises a frame and a covering supported by the frame, the covering being formed of several flexible spacer elements that intersect each other.

The flexible spacer elements may be formed from, e.g., string, cord, braided hose, threads, and/or wire. Other spacer elements are generally also possible as long as they are sufficiently flexible. This flexibility of the spacer elements offers a number of advantages. For instance, flexible spacer elements can adapt to any deformations of a susceptor plate on which the spacer device is to be mounted. Furthermore, such flexible spacer elements can easily be arranged crosswise so that a series of well-defined crossing points of the covering are created. As the covering is essentially twice as thick at these crossing points as at the other areas of the covering, this results in defined contact points for the substrate to be heated, which then essentially rests exclusively at these crossing points on, e.g., the susceptor plate. In other words, these crossing points form discrete spacers between the susceptor plate and the substrate. If the tension of the covering is sufficient, the spacer elements will furthermore neither come into contact with the substrate nor with the susceptor plate. For this purpose, it is particularly preferable that the intersecting spacer elements form a woven structure so that, e.g., each transverse element of the covering is always guided alternately above and below a longitudinal element of the covering.

It is particularly advantageous to provide spacer elements in the form of a covering since such a covering can easily be replaced and the frame provides a well-defined pattern of spacers (i.e., the crossing points) by simple means without having to laboriously arrange them individually, as is the case in, e.g., DE 199 36 081 A1.

The spacer elements should be sufficiently flexible in order to enable, e.g., the above-mentioned woven structure. Preferably, the spacer elements have an E modulus of at most 75 GPa, more preferably of at most 50 GPa, even more preferably of at most 45 GPa, even more preferably of at most 40 GPa, even more preferably of at most 35 GPa, even more preferably of at most 30 GPa, and particularly preferably of at most 25 GPa.

The fill factor of the spacer elements is preferably at least 50%, more preferably at least 65%, even more preferably at least 80%, wherein the fill factor is defined as the proportion of the spacer element material in the entire cross-section of the spacer element.

Preferably, the spacer elements are each formed from string, cord, braided hose, threads, and/or wire. In this context, the term “spacer element” refers to the individual section of the covering that extends from one side of the frame to the opposite side of the frame. In other words, the covering is formed of several spacer elements extending in different directions. In principle, each individual spacer element can be formed from a cord or string or from a wire or braided tube. However, it is preferred that a plurality of spacer elements are formed from one single string or from one single cord or from one single wire or from one single braided tube. For instance, in the case of a rectangular covering pattern consisting of transverse elements and longitudinal elements, all transverse elements could be formed from one single string and all longitudinal elements could be formed from a further string, each of which being deflected at several deflection points on the frame. Particularly preferably, however, all spacer elements are formed from one single string or from one single cord or from one single wire. In this way, the covering according to the invention can be produced or replaced particularly easily and quickly.

Spacer elements made of a string or cord are particularly preferred since their twisted structure further minimizes the thermal conductivity perpendicularly to the longitudinal direction of the string or cord. Spacer elements of this kind may consist of, e.g., quartz, glass, glass fiber composite and/or carbon composite, preferably carbon fiber carbon composite, i.e., CFC. These materials are stable even at the very high temperatures discussed above and offer the advantage of very low thermal conductivity.

However, a flexible wire can also be used instead of a string or cord. Such a wire should preferably also be made of a temperature-stable material that is ideally also inert to the effects of sulphur gases. For example, stainless steel or molybdenum can be used.

Preferably, the spacer elements comprise a diameter of between 0.3 and 3.0 mm, more preferably of between 0.5 and 1.5 mm and particularly preferably of between 0.7 and 1.2 mm. When it comes to spacer elements with a non-circular cross section, these dimensions apply to the expansion perpendicular to the covering plane.

Even if the frame may generally assume any shape, it is preferred that the frame is rectangular or square and the covering comprises longitudinal and transverse elements which extend preferably parallel to the lateral edges of the frame or to the frame members forming the frame. Since in the context of the present invention large-area substrates are meant to be substrates with an area of at least 0.7 m², more preferably at least 1 m², even more preferably at least 2 m², and particularly preferably at least 3 m², it is preferred that the area enclosed by these frame members also comprises these dimensions.

As the substrates may bend during heating, the distance between adjacent spacer elements should not be too great. On the other hand, if the distance between adjacent spacer elements is too small, the shielding may be too large. It is thus preferred that the covering comprises a mesh size between adjacent spacer elements of between 10 and 150 mm, more preferably of between 20 and 100 mm, and particularly preferably of between 30 and 60 mm.

Preferably, the covering comprises at least 50, more preferably at least 200, even more preferably at least 500, and particularly preferably at least 1,000 crossing points per m². Ideally, the frame should be formed from temperature-stable and inert materials. Preferably, the frame is made of graphite and/or carbon fiber carbon composite, i.e., CFC.

As already explained above, one of the reasons why the covering can be replaced quickly is that the covering is deflected at corresponding deflection points on the frame. For this purpose, the frame preferably has several deflection elements around which the covering is guided. These deflection elements can be removed for easy covering of the frame. For instance, a cord can be placed around a corresponding arrangement of deflection elements, which are then attached to the frame together with the covering thus formed.

Alternatively, the frame can also be demountable for covering the frame. For example, the frame can have four frame members that can be easily connected to each other, e.g., by their end sections engaging with each other. These frame members may, e.g., have T-shaped deflection elements around which a corresponding cord may be guided very easily.

According to a further aspect, the present invention provides a heating system for heating large-area substrates. The heating system comprises a susceptor plate with an upper surface and a lower surface, wherein the susceptor plate is opaque to infrared radiation. Furthermore, the heating system comprises a spacer device as described above, which is arranged above the susceptor plate. The spacer device may also be detachably or permanently mounted on the susceptor plate. Finally, the heating system comprises an infrared radiation source which is arranged and configured to heat the underside of the susceptor plate by means of infrared radiation.

According to a further aspect, the present invention provides a heating system for heating large-area substrates. The heating system comprises a susceptor plate having an upper surface and a lower surface, a spacer device as described above arranged above the susceptor plate, and a heating source arranged directly at or in the susceptor plate and adapted to directly heat the susceptor plate.

In the heating system of the latter two aspects, the thermal conductivity of the spacer elements in the direction perpendicular to the plane defined by the susceptor plate is preferably less than 15, preferably less than 12 W/m·K, and particularly preferably less than 6 W/m·K in the entire temperature range between 20° C. and 1,000° C.

Preferably, the susceptor plate of the heating system of the latter two aspects comprises a transmission of less than 10%, more preferably of less than 5%, even more preferably of less than 3%, and particularly preferably of less than 1% for infrared radiation in the entire wavelength range between 0.5 μm and 10.0 μm.

According to a further aspect, the present invention is directed to a method for heating a large-area substrate. For this purpose, a heating system is provided as described above, a large-area substrate is placed in the heating system in such a way that the substrate is supported on the covering, and then the susceptor plate of the heating system is heated.

According to a further aspect, the present invention also provides a heating system for heating large-area substrates. The heating system comprises a susceptor plate with an upper surface and lower surface, wherein the susceptor plate is opaque to infrared radiation. Furthermore, the heating system comprises several spacers above the susceptor plate, which are made of a material with low thermal conductivity. Finally, the heating system comprises an infrared radiation source which is arranged and configured to heat the lower surface of the susceptor plate by means of infrared radiation.

The plurality of spacers of this aspect of the invention may be the spacers of the aspects of the invention described above. In other words, the spacers of this aspect of the invention and of the following description may be crossing points of a covering of flexible spacer elements as described above.

Amongst other things, the invention of this aspect of the invention is based on the fact that the susceptor plate is heated indirectly by means of infrared radiation from the infrared radiation source and then transfers the absorbed energy to the substrate to be heated by means of thermal radiation and/or thermal conduction, wherein homogeneous heating may be achieved due to the spacers as the problem described at the beginning, namely that slight unevenness in the substrate may result in locally varying contact between the substrate and the heating plate, which affects the heating process and leads to considerable temperature inhomogeneities in the substrate, cannot occur. Since the susceptor plate is opaque to infrared radiation, the substrate cannot be heated directly by the infrared radiation source. The good thermal conductivity of the susceptor plate, particularly in the lateral direction, improves the homogeneity of the radiation emitted by the susceptor plate so that any small inhomogeneities of the infrared radiation source may be compensated for. The heating of the substrate by the heated susceptor plate by means of thermal radiation and/or thermal conduction may thus be controlled very precisely.

In the context of the present invention, large-area substrates are considered to be substrates with an area of at least 0.7 m², preferably of at least 1 m², more preferably of at least 2 m², and particularly preferably of at least 3 m². Suitable substrates include, e.g., coated or uncoated glass panes, coated or uncoated silicon wafers with or without electronic components. In principle, however, the invention is suitable for any substrates.

According to a further aspect, the present invention is directed to a heating system for heating large-area substrates. The heating system comprises a susceptor plate having an upper surface and a lower surface as well as several spacers above the susceptor plate, the spacers being made of a material having a low thermal conductivity. Furthermore, the heating system comprises an infrared radiation source which is arranged and configured to heat the lower surface of the susceptor plate by means of infrared radiation. The susceptor plate is to be made of such a material and be dimensioned in such a way that the susceptor plate is heated during the heating test defined below using the reference substrate defined below in such a way that the maximum heating rate of the susceptor plate during the first 20 s of heating is greater than the maximum heating rate of the reference substrate during the first 20 s of heating by at least a factor of 4. This large temperature gradient reflects a very rapid heating of the susceptor plate, which in turn heats the substrate with a time delay by means of heat radiation and, if applicable, thermal conduction through the thermo-conducting gas located between the susceptor plate and the substrate (preferably at atmospheric pressure).

The plurality of spacers of this aspect of the invention may also be the spacers of the aspects of the invention described above. In other words, the spacers of this aspect of the invention and of the following description may be crossing points of a covering of flexible spacer elements as described above.

If there is no vacuum between the upper surface of the susceptor plate and the substrate to be heated, the heating of the substrate is usually based on a combination of thermal radiation, direct thermal conduction at contact points between the susceptor plate and the substrate, and thermal conduction through the fluid between the susceptor plate and the substrate. At small distances, the latter is relatively strongly dependent on the distance so that this component may again lead to inhomogeneities in the heating process. It is therefore preferable to select the distance between the susceptor plate and the substrate in such a way that the thermal conduction becomes very small and is also only very weakly dependent on the distance. It is therefore preferable that this distance is at least 1 mm and particularly preferably at least 2 mm, or that the spacers protrude at least 2 mm from the upper surface of the susceptor plate. More preferably, this distance is at least 2.5 mm and particularly preferably at least 3 mm.

Detailed simulations and experiments have shown that the influence of the gap size between the susceptor plate and the substrate on the heating process is negligible from a minimum distance of around 2 mm. In other words, from a minimum distance of around 2 mm, distance variations caused by, e.g., substrate unevenness no longer play a role, so that appropriately dimensioned spacers allow for very homogeneous heating.

In order to minimize the possible disturbance of the heating process by the spacers, their geometry should be kept as small as possible so that, on the other hand, it is preferred that the spacers protrude at most 10 mm, more preferably at most 8 mm, and particularly preferably at most 5 mm from the upper surface of the susceptor plate.

For a rapid heating process of the substrate, it is further preferred that the temperature of the susceptor plate during the heating process is significantly higher than that of the substrate. Accordingly, the susceptor plate is preferably formed from such a material and dimensioned such that the susceptor plate is heated during the heating test defined below using the reference substrate defined below such that the maximum temperature difference between the susceptor plate and the reference substrate during the first 90 s of heating is at least 100 K, preferably at least 200 K, more preferably at least 300 K, even more preferably at least 400 K, and particularly preferably at least 500 K. These high initial temperature differences also reflect the very rapid heating of the susceptor plate and the high radiant power of the susceptor plate on the substrate associated therewith.

In the context of the present invention, infrared radiation is understood as the wavelength range between 0.5 μm and 10.0 μm. Accordingly, the susceptor plate preferably has a transmission of less than 10%, more preferably of less than 5%, even more preferably of less than 3%, and particularly preferably of less than 1% for electromagnetic radiation in the entire wavelength range between 0.5 μm and 10.0 μm. It may be sufficient if these transmission values are averaged over the entire wavelength range between 0.5 μm and 10.0 μm since ultimately only the cumulative heating power is important. However, it is preferable that these transmission values are actually achieved over the entire wavelength range between 0.5 μm and 10.0 μm for each individual wavelength. If the infrared radiation source only emits infrared radiation of a certain wavelength band (or several bands), it is sufficient for the susceptor plate to comprise the mentioned transmission values for infrared radiation within this wavelength band (or these bands) since increased transmission for radiation that is not emitted is harmless.

The high degree of absorption of the susceptor plate causes initial heating of the susceptor plate exclusively and, afterwards, of the substrate by the sharply rising temperature of the susceptor plate. The high degree of absorption of the susceptor plate and the indirect heating of the substrate are defined by measuring the heating temperatures of the susceptor plate and the substrate. It is also advantageous that the susceptor plate has a low thickness and thermal capacity in order to achieve a rapid heating process.

It is also preferred that the susceptor plate for electromagnetic radiation in the entire wavelength range between 0.5 μm and 10.0 μm has a degree of absorption of at least 45%, more preferably of at least 50%, and particularly preferably of at least 55%. Here too, a corresponding average absorption may be sufficient. However, it is preferable that these absorption levels are achieved for all wavelengths. The absorption of the susceptor plate can be further increased by appropriate measures such as, e.g., structuring the surface or increasing the surface roughness or by coating it with graphite. Absorption levels of at least 65%, more preferably of at least 75%, and particularly preferably of at least 85% are then also possible.

It is also preferred that the susceptor plate for electromagnetic radiation has an emissivity of at least 45%, more preferably of at least 50%, and particularly preferably of at least 55% in the entire wavelength range between 0.5 μm and 10.0 μm. Here too, a corresponding average emission may be sufficient. However, it is preferable that these emissivity levels are achieved for all wavelengths. The emission of the susceptor plate can be further increased by appropriate measures such as, e.g., structuring the surface or increasing the surface roughness or by coating it with graphite. Emissivity levels of at least 65%, more preferably of at least 75%, and particularly preferably of at least 85% are then also possible.

The above-mentioned values for transmission, absorption and emission may generally apply to the susceptor plate. However, with regard to the functionality of the susceptor plate, it is particularly desirable that the absorption levels are achieved for the lower surface and the emission levels are achieved for the upper surface of the susceptor plate. The mentioned transmission values should apply in particular to a transmission directed from bottom to top (of course, this applies vice versa to the optional susceptor plate above the substrate; see below).

According to a further aspect, the present invention is directed to a heating system for heating large-area substrates, which heating system comprises a susceptor plate having an upper surface and a lower surface, a plurality of spacers above the susceptor plate and a heating source which is arranged directly at or in the susceptor plate and is configured to heat the susceptor plate directly. The plurality of spacers preferably consist of a material with low thermal conductivity, wherein the spacers protrude at least 1 mm, preferably at least 2 mm, and particularly preferably at least 3 mm from the upper surface of the susceptor plate.

The plurality of spacers of this aspect of the invention may also be the spacers of the aspects of the invention described above. In other words, the spacers of this aspect of the invention and of the following description may be crossing points of a covering of flexible spacer elements as described above.

Since in this aspect of the invention the susceptor plate is not heated by means of infrared radiation, it is not necessary for this aspect that the susceptor plate is opaque to infrared radiation. Preferably, however, no image of the geometry of the heating source should be generated in the temperature distribution of the substrate. The heating source can, e.g., be a resistance heater integrated into the susceptor plate. The resistance heater is preferably designed in such a way that the surface of the susceptor plate has a homogeneous temperature distribution, wherein the thermal conduction within the susceptor plate also improves the homogeneous temperature distribution.

The susceptor plate of this aspect of the invention also preferably consists of a material that corresponds to the heating tests defined above for the other aspects of the invention.

The preferred features described below are relevant for all aspects of the present invention described above.

The thermal conductivity of the spacers in the entire temperature range between 20° C. and 1,000° C. is preferably less than 15 W/m·K, more preferably less than 12 W/m·K, more preferably less than 6.0 W/m·K, even more preferably less than 4.5 W/m·K, and particularly preferably less than 3.0 W/m·K. Since the materials used for the spacers can also be anisotropic, it is particularly preferred that the thermal conductivity of the spacers in the direction perpendicular to the substrate plane is in the entire temperature range between 20° C. and 1,000° C., preferably less than 15 W/m·K, more preferably less than 12 W/m·K, more preferably less than 6.0 W/m·K, even more preferably less than 4.5 W/m·K, and particularly preferably less than 3.0 W/m·K. The thermal conductivity of the spacers can be determined using conventional methods such as the laser flash method, the Transient Hot Bridge method, or by means of a heat flow meter (e.g., using the A-Meter EP500e from Lambda-Meßtechnik GmbH Dresden). A particularly preferred measurement method in the context of the present invention is the needle probe method according to ASTM D5334-08.

Preferably, the spacers should be shaped such that the supporting surface or the contact area between the substrate and the spacer is minimized. Preferably, the entire (summed) contact area between the substrate and all spacers is a maximum of 5%, more preferably a maximum of 1%, particularly preferably a maximum of 0.1% of the substrate surface. The thicker the substrate, the better temperature inhomogeneities within the substrate can be compensated for by lateral thermal conduction in the substrate. Thus, a particularly small supporting surface is advantageous for particularly thin substrates. It is therefore preferable that the width of the supporting surface of spacers extending continuously along the transverse and/or longitudinal direction of the substrate is less than 50%, preferably less than 20%, and particularly preferably less than 10% of the substrate thickness. In the case of insulated spacers, it is preferred that the diameter or the maximum dimension of the supporting surface of a spacer is less than 50%, preferably less than 20%, and particularly preferably less than 10% of the substrate thickness.

In order to minimize the disturbance of the energy transfer from the susceptor plate to the substrate by means of thermal radiation, it is advantageous if the spacers shade as little area of the substrate as possible. It is therefore preferred that the entire projection area of all spacer elements or the entire covering (projected perpendicular to the substrate surface) is at most 10%, preferably at most 6%, particularly preferably at most 3% of the substrate surface.

Furthermore, it is preferable to provide several spacers in order to support the substrate as evenly as possible. This is particularly relevant for glass substrates and heating beyond the softening point. In order to prevent resultant deflection of the heated substrate as far as possible, it is preferable that the maximum unsupported distance between two spacers is less than 10 cm, more preferably less than 5 cm, and particularly preferably less than 3 cm.

Corresponding simulations for parallel spacers have shown that supporting a glass plate with a thickness of 2 mm on spacers at a distance of 5 cm for a period of 5 min results in a maximum deflection of 0.2 mm, which is considered tolerable. Analogous calculations were carried out for discrete support points in a regular square pattern. In this case, a diagonal of the square pattern (i.e., in turn, the unsupported distance) of at most 5 cm led to good results.

The thickness of the susceptor plate is preferably less than 5 mm, more preferably less than 3 mm, and particularly preferably less than 2 mm. For instance, plates made of fiber-reinforced carbons (so-called CFC materials) can be used.

The upper surface of the susceptor plate preferably has an area of at least 0.7 m², more preferably of at least 1 m², more preferably of at least 2 m², and particularly preferably of at least 3 m².

In addition to the infrared radiation source or the heating source, a (further) infrared radiation source may be provided, which is arranged and configured to heat the upper surface of the susceptor plate or the substrate by means of infrared radiation. It is particularly preferred that heating is also carried out indirectly from this side by means of a susceptor plate. Thus, it is also preferred that a further susceptor plate with an upper surface and a lower surface is provided, wherein the susceptor plate is not opaque to infrared radiation. Furthermore, a (further) infrared radiation source is preferably provided, which is arranged and configured to heat the upper surface of the further susceptor plate by means of infrared radiation. The properties described above with regard to the lower susceptor plate also preferably apply to the upper susceptor plate, in particular also with regard to the optical parameters and the heating behavior.

In order to make sure that the substrate is heated as homogeneously as possible, it is preferred that the (upper and/or lower) susceptor plate has a lateral thermal conductivity within the susceptor plate plane of at least 10 W/m·K, more preferably of at least 30 W/m·K, and particularly preferably of at least 50 W/m·K in the entire temperature range between 20° C. and 1,000° C.

The present invention is further directed to a method of heating a large-area substrate using the heating system described above (according to all aspects). The method comprises introducing a large-area substrate into the heating system such that the substrate is supported on the spacers. The method further comprises heating the susceptor plate, wherein the substrate supported on the spacers is then heated primarily by means of thermal radiation.

Furthermore, the present invention is directed to a method of heating a large-area substrate comprising the following steps:
Providing a heating system comprising a susceptor plate having an upper surface and a lower surface, a spacer device above the susceptor plate as described above, and an infrared radiation source arranged and configured to heat the lower surface of the susceptor plate by means of infrared radiation;
introducing a large-area substrate into the heating system such that the substrate is supported on the covering; and
heating the susceptor plate, preferably while the substrate is resting on the covering.

The susceptor plate is preferably heated using the infrared radiation source in such a way that the maximum heating rate of the susceptor plate during the first 20 s of heating is greater than the maximum heating rate of the substrate during the first 20 s of heating by at least a factor of 4, preferably by at least a factor of 6, more preferably by at least a factor of 10. Preferably, the maximum temperature difference between the susceptor plate and the substrate during the first 90 s of heating is at least 100 K, preferably at least 200 K, more preferably at least 300 K, even more preferably at least 400 K, and particularly preferably at least 500 K.

Preferably, the substrate comprises an area of at least 0.7 m², more preferably of at least 1 m², even more preferably of at least 2 m² and particularly preferably of at least 3 m².

The susceptor plate is preferably heated to a temperature of at least 600° C., more preferably of at least 800° C., and particularly preferably of at least 1,000° C.

The substrate is heated over its entire surface by the heated susceptor plate primarily by means of thermal radiation, with the substrate being heated at a rate of at least 2 K/s, more preferably of at least 3 K/s, and particularly preferably of at least 4 K/s. Furthermore, the heating rate is preferably less than 18 K/s, more preferably less than 15 K/s, and particularly preferably less than 10 K/s. According to the invention, a high initial heating rate of the susceptor plate is particularly advantageous in order to quickly ensure a high energy transfer from the susceptor plate to the substrate. It is therefore preferred that the susceptor plate is heated to a temperature of at least 300° C., preferably of at least 400° C., and particularly preferably of at least 500° C. during the first 20 s of heating.

Preferably, the substrate is heated up to a temperature of at most 700° C., more preferably of at most 650° C., and particularly preferably of at most 600° C. Preferably, the substrate is heated up to a temperature of at least 300° C., more preferably of at least 400° C., and particularly preferably of at least 500° C.

The heating process is preferably carried out in the presence of a process gas. The gas can be an inert gas, e.g., nitrogen or argon, a reactive gas or a mixture of an inert gas and a reactive gas. The gas pressure between the susceptor plate and the substrate is preferably at least 20 mbar, more preferably at least 100 mbar, even more preferably at least 200 mbar, and particularly preferably atmospheric pressure.

The distance between the upper surface of the susceptor plate and the lower surface of the substrate is preferably at least 1 mm, more preferably at least 2 mm, and particularly preferably at least 3 mm. Furthermore, the distance between the upper surface of the susceptor plate and the lower surface of the substrate is preferably at most 10 mm, more preferably at most 8 mm, and particularly preferably at most 5 mm.

As already mentioned, the minimum distance of 2 mm leads to particularly homogeneous heating within the substrate. In this context, it is preferred that the substrate is heated homogeneously during the entire heating process in such a way that the temperature difference occurring in the substrate surface in the area of a spacer is at most 75 K, preferably at most 50 K, and particularly preferably at most 25 K during the entire heating process. This can be measured using, e.g., an infrared camera. With the help of an infrared camera, it is possible to evaluate an area of, e.g., 50 mm×50 mm, which has at least one supporting surface on at least one spacer in the most symmetrical way possible. The maximum difference of all temperatures determined within this area is determined at each measurement time. Preferably, this maximum difference is to be at most 75 K for all measurement times, more preferably at most 50 K, and particularly preferably at most 25 K.

Preferably, the entire contact area between the substrate and all spacers is at most 5%, preferably at most 1%, particularly preferably at most 0.1% of the substrate surface. As already stated above, it is preferred that the width of the contact line of spacers extending continuously along the transverse and/or longitudinal direction of the substrate is less than 50%, preferably less than 20%, and particularly preferably less than 10% of the substrate thickness. In the case of segregate spacers, it is preferred that the diameter or the maximum dimension of the supporting surface of a spacer is less than 50%, preferably less than 20%, and particularly preferably less than 10% of the substrate thickness.

Preferably, the entire projection area of the covering is at most 10%, preferably at most 6%, particularly preferably at most 3% of the substrate surface.

Preferably, the maximum unsupported distance between the supporting surfaces of two spacers is at most 10 cm, preferably at most 5 cm, particularly preferably at most 3 cm.

Furthermore, in the context of the methods according to the invention, the heating system may comprise a further susceptor plate with an upper surface and a lower surface as well as a further infrared radiation source which is arranged and configured to heat the upper surface of the further susceptor plate by means of infrared radiation. In doing so, the large-area substrate is introduced into the heating system in such a way that the substrate is supported between the two susceptor plates on the spacers. The distance between the lower surface of the additional susceptor plate and the upper surface of the substrate is also preferably at least 1 mm, more preferably at least 2 mm.

The present invention describes an advantageous heating system and an advantageous heating method for the case in which a large-area substrate (e.g., a large-area glass pane) is placed on a susceptor plate that is rapidly heated by, e.g., IR emitters, wherein a homogeneous temperature distribution is achieved within the large-area substrate. Various features of the invention work together synergistically. For example, the spacers, in particular at a distance of at least 2 mm, enable a uniform energy supply since variations in the gap width above this minimum distance have no significant influence on the thermal conduction through the process gas. In order to enable high heating rates of the substrate at these distances, very rapid heating of the susceptor plate is provided, which is reflected in correspondingly large initial temperature differences and heating rate ratios between the susceptor plate and the substrate. Supporting the substrate on the spacers can in turn lead to the substrate (e.g., the glass pane) bending between the spacers when the substrate is heated to the glass transition temperature range and when the heated substrate is supported for a longer period of time. This can be effectively avoided by setting a corresponding maximum distance between the spacers depending on the temperature (and the resulting viscosity) and the storage time.

The present invention is further directed to the following aspects. It is explicitly envisaged to combine the features of these following aspects with the features of the claims such that the “spacers” of the following aspects are formed by crossing points of the covering formed by spacer elements.

1. A heating system for heating large-area substrates, the heating system comprising:
a susceptor plate with an upper surface and a lower surface, wherein the susceptor plate is opaque to infrared radiation;
several spacers above the susceptor plate which consist of a material with low thermal conductivity and protrude at least 1 mm from the upper surface of the susceptor plate; and
an infrared radiation source which is arranged and configured to heat the lower surface of the susceptor plate by means of infrared radiation.

2. A heating system for heating large-area substrates, the heating system comprising:
a susceptor plate with an upper surface and a lower surface;
several spacers above the susceptor plate which consist of a material with low thermal conductivity; and
an infrared radiation source which is arranged and configured to heat the lower surface of the susceptor plate by means of infrared radiation;
wherein the susceptor plate is formed from such a material and dimensioned such that the susceptor plate is heated during the heating test defined in the description using the reference substrate defined in the description in such a way that the maximum heating rate of the susceptor plate during the first 20 s of heating is greater than the maximum heating rate of the reference substrate during the first 20 s of heating by at least a factor of 4.

3. The heating system according to aspect 2, wherein the maximum heating rate of the susceptor plate during the first 20 s of heating is greater than the maximum heating rate of the substrate during the first 20 s of heating by at least a factor of 4, preferably by at least a factor of 6, more preferably by at least a factor of 10.

4. The heating system according to aspect 2 or 3, wherein the susceptor plate is preferably formed from such a material and dimensioned such that the susceptor plate is heated during the heating test defined in the description using the reference substrate defined in the description such that the maximum temperature difference between the susceptor plate and the reference substrate during the first 90 s of heating is at least 100 K, preferably at least 200 K, more preferably at least 300 K, even more preferably at least 400 K, and particularly preferably at least 500 K.

5. The heating system according to any one of the preceding aspects, wherein the spacers protrude at least 1 mm, preferably at least 2 mm, and particularly preferably at least 3 mm from the upper surface of the susceptor plate.

6. A heating system for heating large-area substrates, the heating system comprising:
a susceptor plate with an upper surface and a lower surface;
several spacers above the susceptor plate consisting of a material with low thermal conductivity, wherein the spacers protrude at least 1 mm from the upper side of the susceptor plate; and
a heating source which is arranged directly at or in the susceptor plate and configured to directly heat the susceptor plate.

7. The heating system according to aspect 6, wherein the spacers protrude at least 2 mm from the upper surface of the susceptor plate.

8. The heating system according to aspect 6 or 7, wherein the susceptor plate is formed from such a material and dimensioned such that the susceptor plate is heated during the heating test defined in the description using the reference substrate defined in the description in such a way that the maximum heating rate of the susceptor plate during the first 20 s of heating is greater than the maximum heating rate of the reference substrate during the first 20 s of heating by at least a factor of 4, preferably by at least a factor of 6, particularly preferably by at least a factor of 10.

9. The heating system according to aspect 6, 7, or 8, wherein the susceptor plate is preferably formed from such a material and dimensioned such that the susceptor plate is heated during the heating test defined in the description using the reference substrate defined in the description such that the maximum temperature difference between the susceptor plate and the reference substrate during the first 90 s of heating is at least 100 K, preferably at least 200 K, more preferably at least 300 K, even more preferably at least 400 K, and particularly preferably at least 500 K.

10. The heating system according to any one of the preceding aspects, wherein the thermal conductivity of the spacers in the direction perpendicular to the plane defined by the susceptor plate is less than 15 W/m·K, preferably less than 12 W/m·K, particularly preferably less than 6.0 W/m·K in the entire temperature range between 20° C. and 1,000° C.

11. The heating system according to any one of the preceding aspects, wherein the spacers protrude at most 10 mm, preferably at most 8 mm, and particularly preferably at most 5 mm from the upper surface of the susceptor plate.

12. The heating system according to any one of the preceding aspects, wherein the thickness of the susceptor plate is smaller than 5 mm, preferably smaller than 3 mm, particularly preferably smaller than 2 mm.

13. The heating system according to any one of the preceding aspects, wherein the upper surface of the susceptor plate comprises an area of at least 0.7 m², preferably of at least 1 m², more preferably of at least 2 m², and particularly preferably of at least 3 m².

14. The heating system according to any one of the preceding aspects, wherein the susceptor plate comprises a transmission of less than 10%, preferably of less than 5%, more preferably of less than 3%, and particularly preferably of less than 1% for infrared radiation in the entire wavelength range between 0.5 μm and 10.0 μm.

15. The heating system according to any one of the preceding aspects, wherein the susceptor plate for electromagnetic radiation in the entire wavelength range between 0.5 μm and 10.0 μm has a degree of absorption of at least 45%, preferably of at least 50%, and more preferably of at least 55%.

16. The heating system according to any one of the preceding aspects, further comprising a (further) infrared radiation source which is arranged and configured to heat the upper surface of the susceptor plate by means of infrared radiation.

17. The heating system according to any one of the preceding aspects, further comprising a further susceptor plate comprising an upper surface and a lower surface and a (further) infrared radiation source which is arranged and configured to heat the upper surface of the further susceptor plate by means of infrared radiation.

18. The heating system according to aspect 17, wherein the susceptor plate is opaque to infrared radiation.

19. The heating system according to aspect 17 or 18, wherein the further susceptor plate is formed from such a material and dimensioned such that the further susceptor plate is heated during the heating test defined in the description using the reference substrate defined in the description in such a way that the maximum heating rate of the further susceptor plate during the first 20 s of heating is greater than the maximum heating rate of the reference substrate during the first 20 s of heating by at least a factor of 4, preferably by at least a factor of 6, particularly preferably by at least a factor of 10.

20. The heating system according to aspect 17, 18, or 19, wherein the further susceptor plate is formed from such a material and dimensioned such that the further susceptor plate is heated during the heating test defined in the description using the reference substrate defined in the description such that the maximum temperature difference between the susceptor plate and the reference substrate during the first 90 s of heating is at least 100 K, preferably at least 200 K, more preferably at least 300 K, even more preferably at least 400 K, and particularly preferably at least 500 K.

21. The heating system according to any one of the preceding aspects, wherein the susceptor plate and/or the further susceptor plate comprises a lateral thermal conductivity within the susceptor plate plane of at least 10 W/m·K, preferably of at least 30 W/m·K, particularly preferably of at least 50 W/m·K in the entire temperature range between 20° C. and 1,000° C.

22. The heating system according to any one of the preceding aspects, wherein the spacers are arranged on the upper surface of the susceptor plate.

23. The heating system according to any one of the preceding aspects, wherein the entire contact area between the substrate and all spacers is at most 5%, preferably at most 1%, particularly preferably at most 0.1% of the substrate surface.

24. The heating system according to any one of the preceding aspects, wherein the entire projection area of all spacer elements is at most 15%, preferably at most 12%, particularly preferably at most 9% of the substrate surface.

25. The heating system according to any one of the preceding aspects, wherein the maximum unsupported distance between the supporting surfaces of two spacers is at most 10 cm, preferably at most 5 cm, particularly preferably at most 3 cm.

26. A method for heating a large-area substrate, the method comprising the following steps:
providing a heating system according to any one of the preceding aspects;
introducing a large-area substrate into the heating system such that the substrate is supported on the spacers; and
heating the susceptor plate.

27. A method for heating a large-area substrate, the method comprising the following steps:
providing a heating system comprising a susceptor plate with an upper surface and a lower surface, several spacers above the susceptor plate which consist of a material with low thermal conductivity, and an infrared radiation source which is arranged and configured to heat the lower surface of the susceptor plate by means of infrared radiation;
introducing a large-area substrate into the heating system such that the substrate is supported on the spacers; and
heating the susceptor plate.

28. The method according to aspect 27, wherein the susceptor plate is heated using the infrared radiation source in such a way that the maximum heating rate of the susceptor plate during the first 20 s of heating is greater than the maximum heating rate of the substrate during the first 20 s of heating by at least a factor of 4, preferably by at least a factor of 6, more preferably by at least a factor of 10.

29. The method according to any one of aspects 27 to 28, wherein the maximum temperature difference between the susceptor plate and the substrate during the first 90 s of heating is at least 100 K, preferably at least 200 K, more preferably at least 300 K, even more preferably at least 400 K, and particularly preferably at least 500 K.

30. The method according to any one of aspects 27 to 29, wherein the substrate comprises an area of at least 0.7 m², preferably of at least 1 m², more preferably of at least 2 m², and particularly preferably of at least 3 m².

31. The method according to any one of aspects 27 to 30, wherein the susceptor plate is heated to a temperature of at least 300° C., preferably of at least 350° C., and particularly preferably of at least 400° C. during the first 20 s of heating.

32. The method according to any one of aspects 27 to 31, wherein the substrate is heated over its entire surface by the heated susceptor plate by means of thermal radiation, wherein the substrate is heated at a rate of at least 2 K/s, preferably of at least 3 K/s, and particularly preferably of at least 4 K/s, and/or of at most 18 K/s, preferably of at most 15 K/s, and particularly preferably of at most 10 K/s.

33. The method according to aspect 32, wherein the substrate is heated up to a temperature of at most 700° C., more preferably of at most 650° C., and particularly preferably of at most 600° C.

34. The method according to aspect 32 or 33, wherein the substrate is heated up to a temperature of at least 300° C., preferably of at least 400° C., and particularly preferably of at least 500° C.

35. The method according to aspect 32, 33, or 34, wherein the substrate is heated homogeneously during the entire heating process such that the temperature difference occurring in the substrate surface in the region of the spacers is at most 75 K, preferably at most 50 K, and particularly preferably at most 25 K.

36. The method according to any one of aspects 27 to 35, wherein a gas pressure of at least 20 mbar, preferably of at least 100 mbar, and particularly preferably atmospheric pressure is present between the susceptor plate and the substrate.

37. The method according to any one of aspects 27 to 36, wherein the distance between the upper surface of the susceptor plate and the lower surface of the substrate is at least 1 mm, preferably at least 2 mm.

38. The method according to any one of aspects 27 to 37, wherein the distance between the upper surface of the susceptor plate and the lower surface of the substrate is at most 10 mm, preferably at most 8 mm, and particularly preferably at most 5 mm.

39. The method according to any one of aspects 27 to 38, wherein the entire contact area between the substrate and all spacers is at most 5%, preferably at most 1%, particularly preferably at most 0.1% of the substrate surface.

40. The method according to any one of aspects 27 to 39, wherein the width of the contact line of spacers extending continuously along the transverse and/or longitudinal direction of the substrate is less than 50%, preferably less than 20%, and particularly preferably less than 10% of the substrate thickness, or wherein the diameter or the maximum dimension of the supporting surface of one spacer is smaller than 50%, preferably smaller than 20%, and particularly smaller than 10% of the substrate thickness.

41. The method according to any one of aspects 27 to 40, wherein the entire projection surface of all spacers is at most 10%, preferably at most 6%, particularly preferably at most 3% of the substrate surface.

42. The method according to any one of aspects 27 to 41, wherein the maximum unsupported distance between the supporting surfaces of two spacers is at most 10 cm, preferably at most 5 cm, particularly preferably at most 3 cm.

43. The method according to any one of aspects 27 to 42, wherein the heating system further comprises a further susceptor plate with an upper surface and a lower surface and a further infrared radiation source which is arranged and configured to heat the upper surface of the further susceptor plate by means of infrared radiation, and wherein the large-area substrate is introduced into the heating system such that the substrate is supported between the two susceptor plates on the spacers.

44. The method according to aspect 43, wherein the distance between the lower surface of the further susceptor plate and the upper surface of the substrate is at least 1 mm, preferably at least 2 mm.

In the following, preferred embodiments of the present invention will be described in more detail with respect to the figures, in which

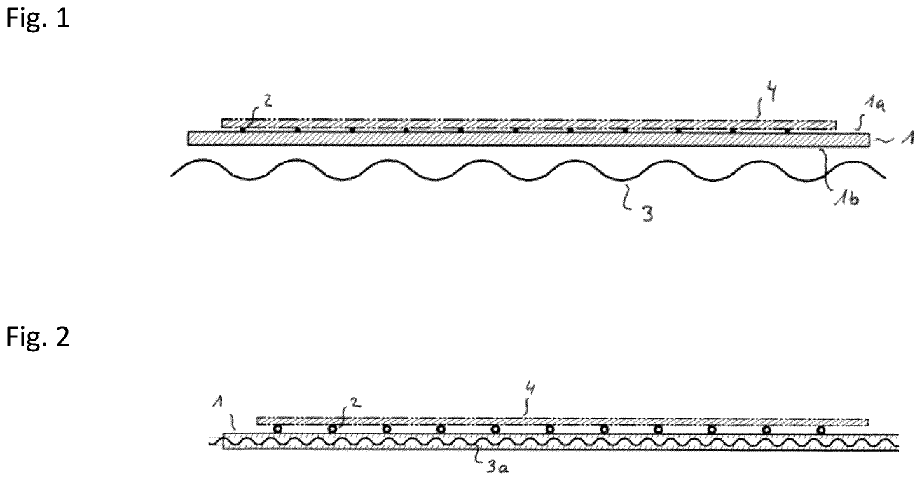

FIG. 1 shows a schematic sectional view through a heating system according to a preferred embodiment of the present invention;

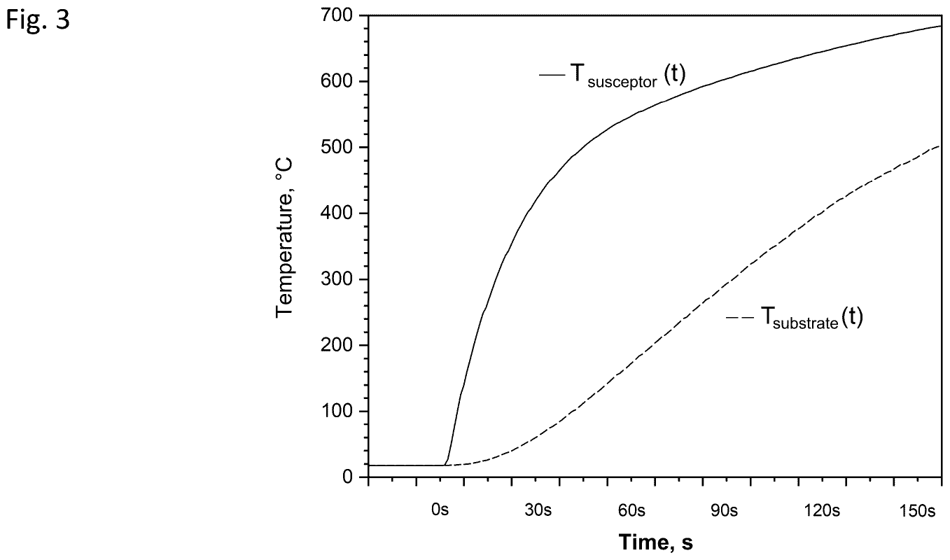

FIG. 2 shows a schematic sectional view through a heating system according to a further preferred embodiment of the present invention;

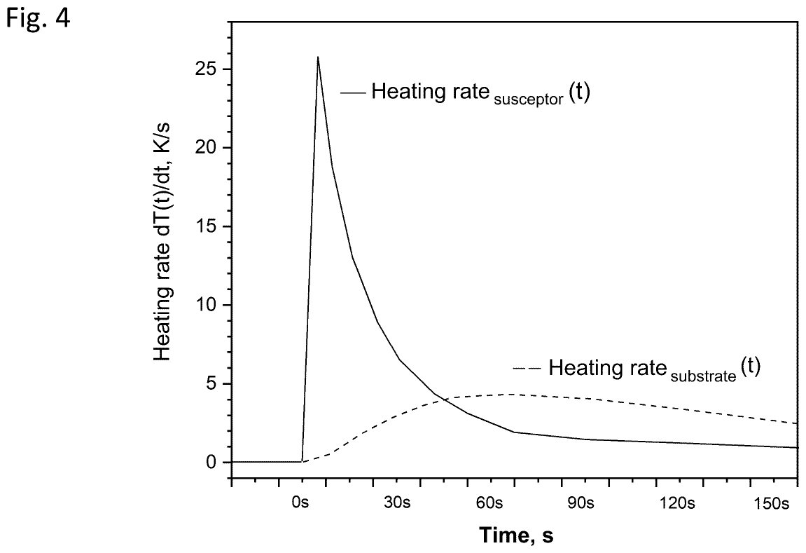

FIG. 3 shows the temperature profile over time of a susceptor plate and a substrate in the method according to the invention;

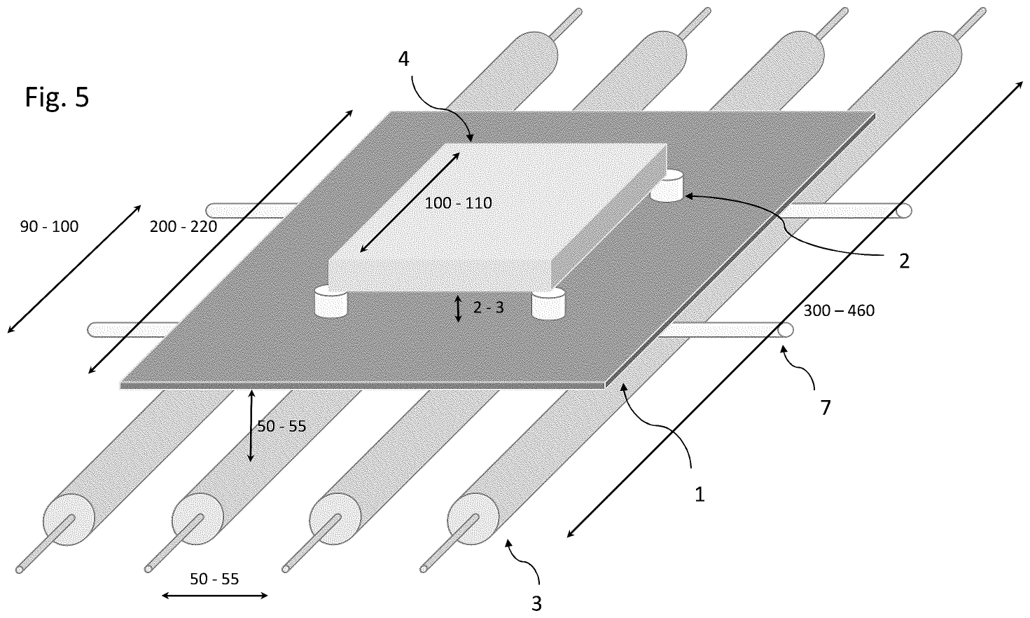

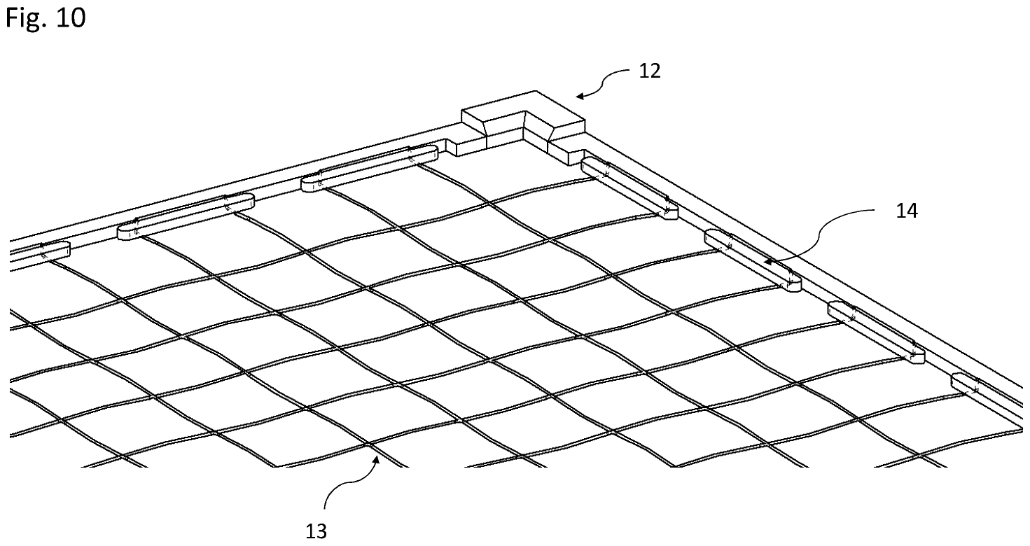

FIG. 4 shows the heating rates determined from the temperature profiles according to FIG. 10;

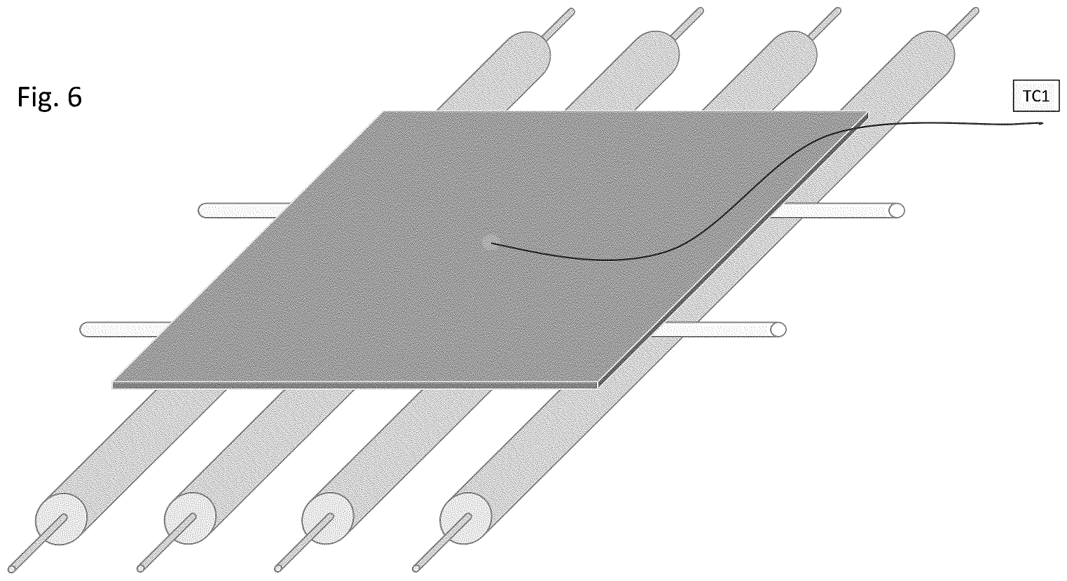

FIG. 5 schematically shows a measuring arrangement for the heating test;

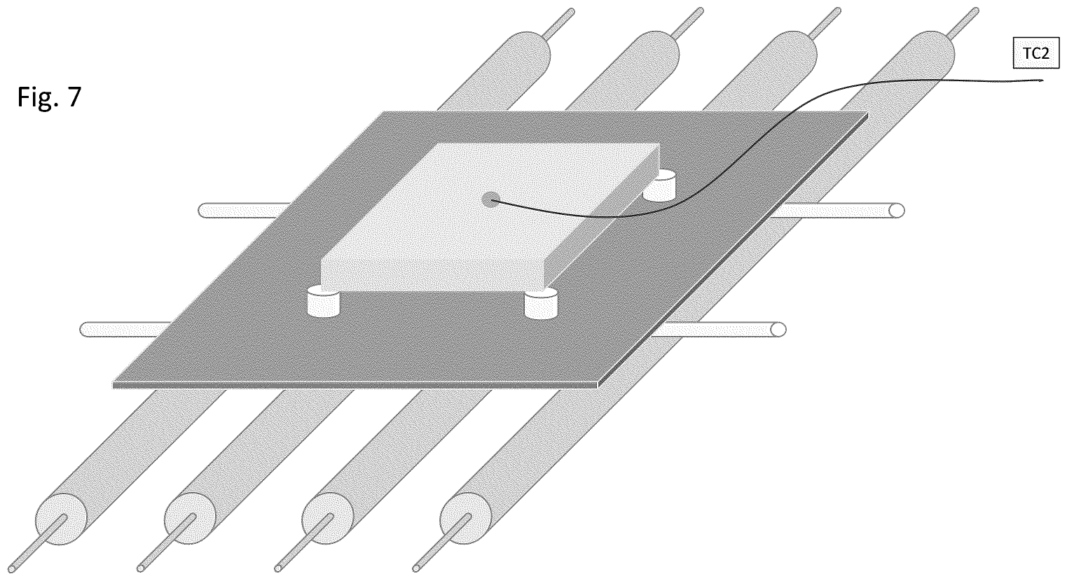

FIG. 6 schematically shows the placement of the thermocouple TC1 for the heating test;

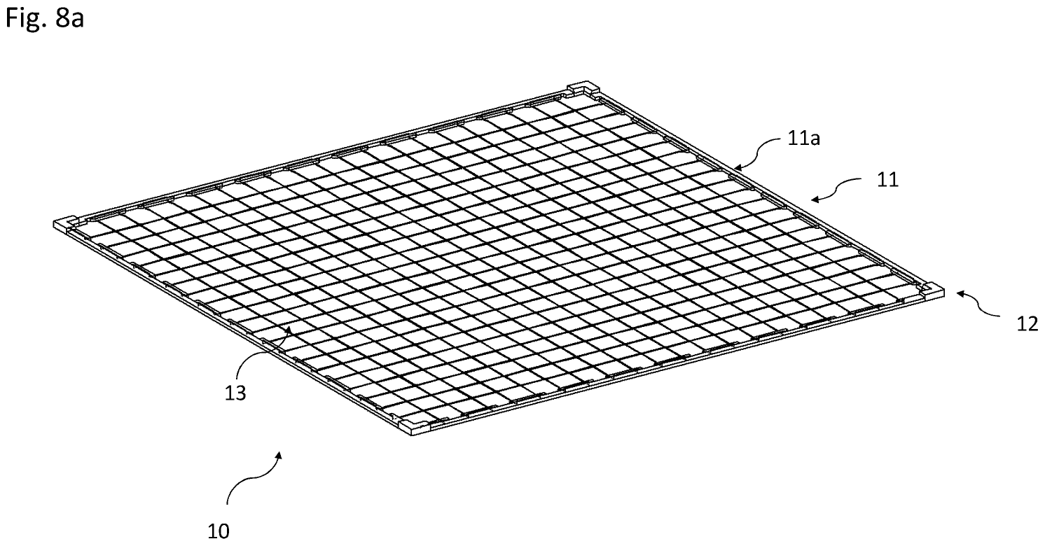

FIG. 7 schematically shows the placement of the thermocouple TC2 for the heating test;

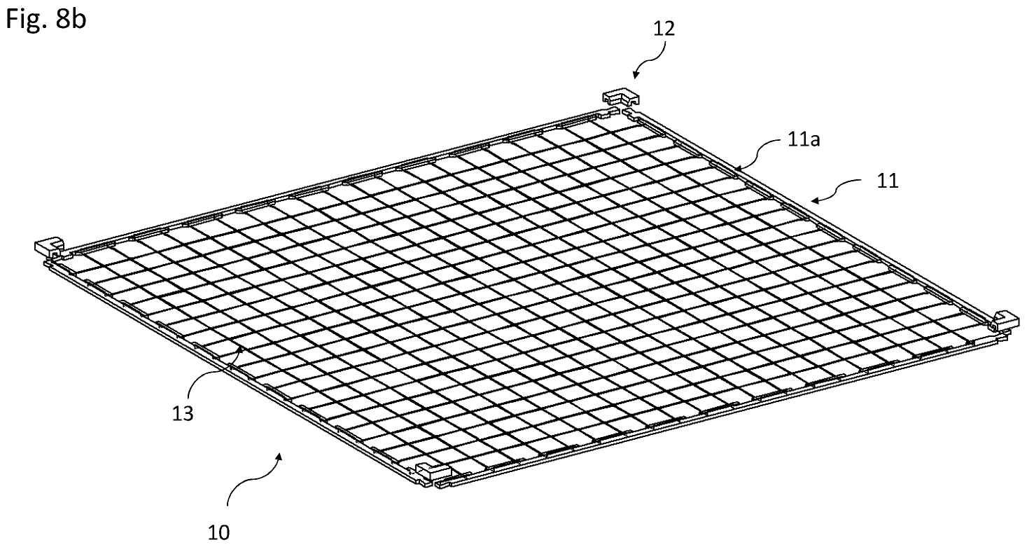

FIG. 8a shows a perspective view of a spacer for a heating system according to a preferred embodiment of the present invention;

FIG. 8b shows a perspective view of the spacer according to FIG. 8a in the disassembled state;

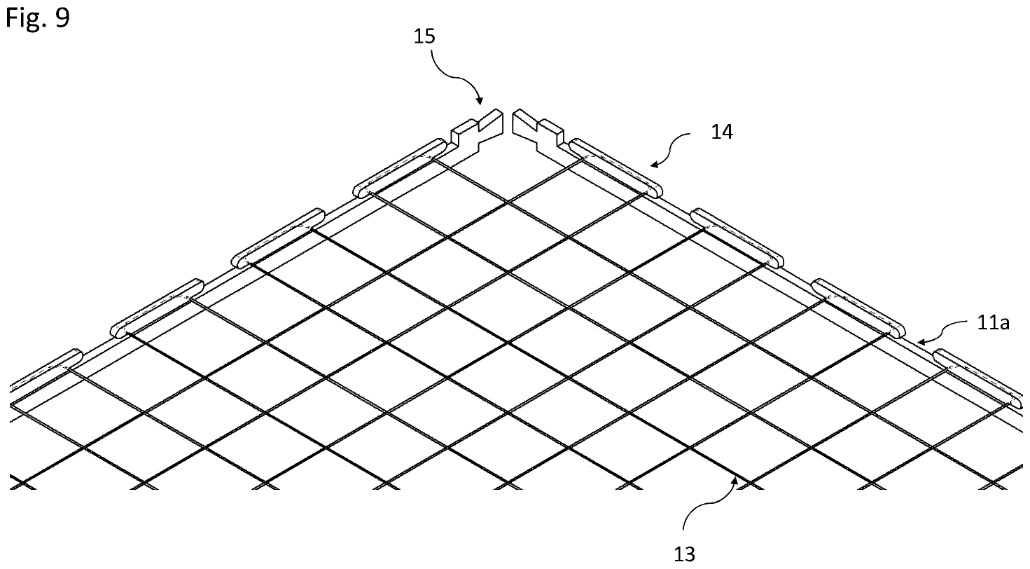

FIG. 9 shows the disassembled frame of the spacer according to FIG. 8;

FIG. 10 shows the assembled frame of the spacer according to FIG. 8;

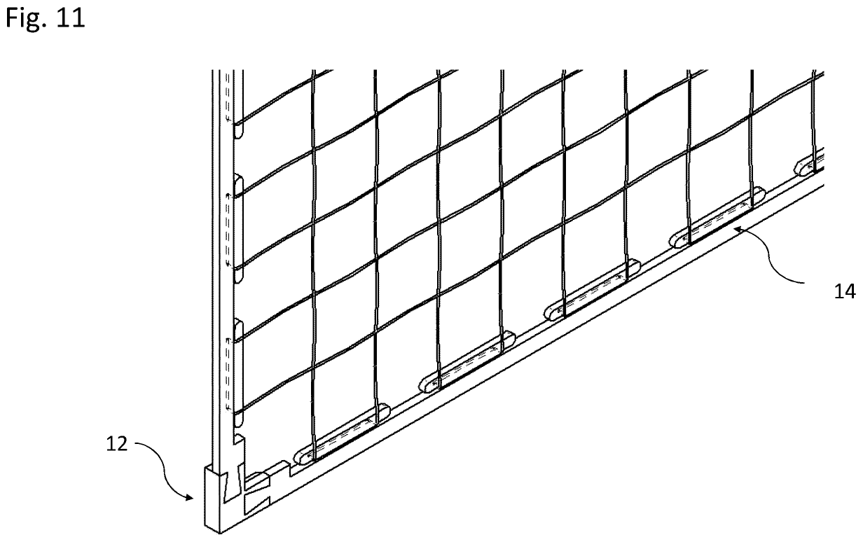

FIG. 11 shows a perspective view from below of the frame according to FIG. 10;

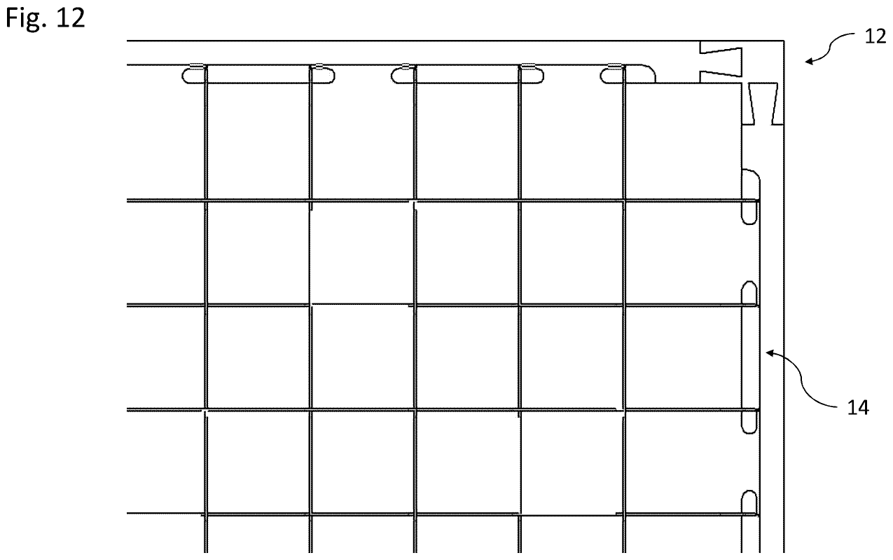

FIG. 12 shows a top view from below of the frame according to FIG. 10;

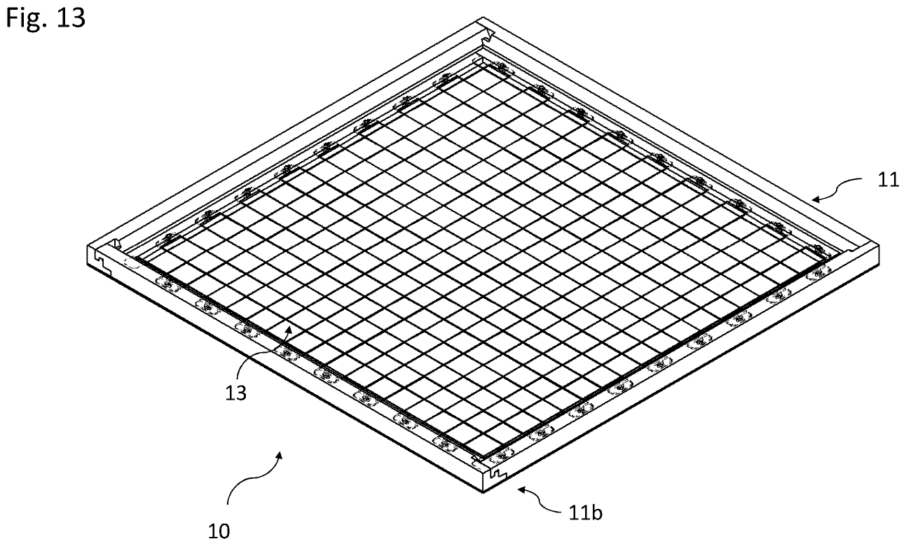

FIG. 13 shows a perspective view of a spacer for a heating system according to a further preferred embodiment of the present invention;

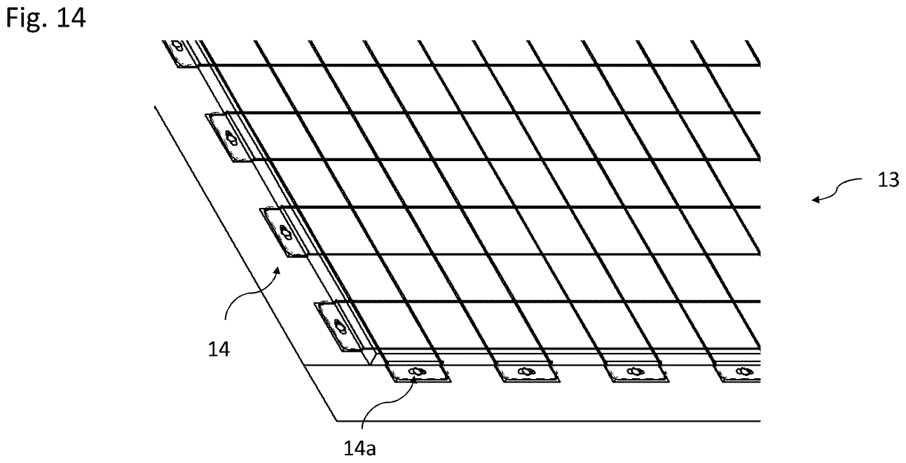

FIG. 14 shows a perspective detailed view from below of the spacer according to FIG. 13;

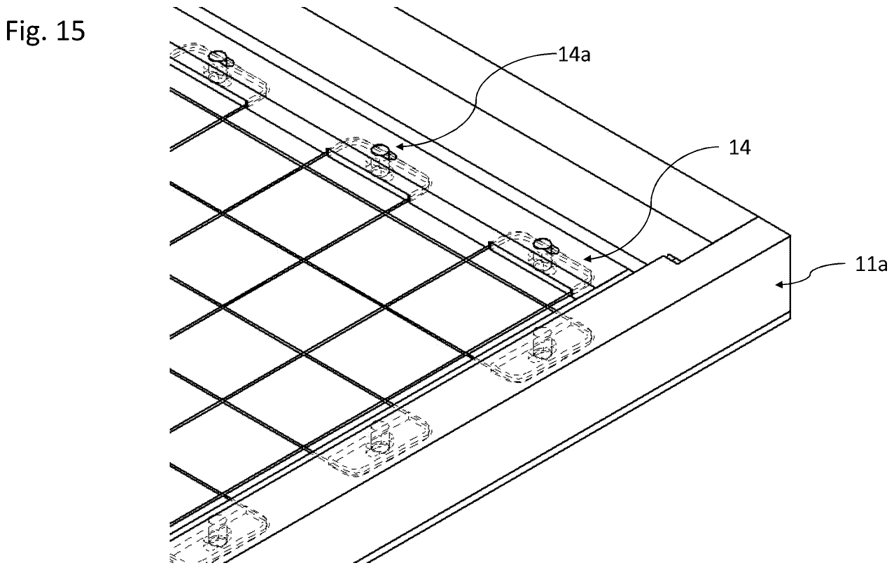

FIG. 15 shows a perspective detailed view from above of the spacer according to FIG. 13; and.

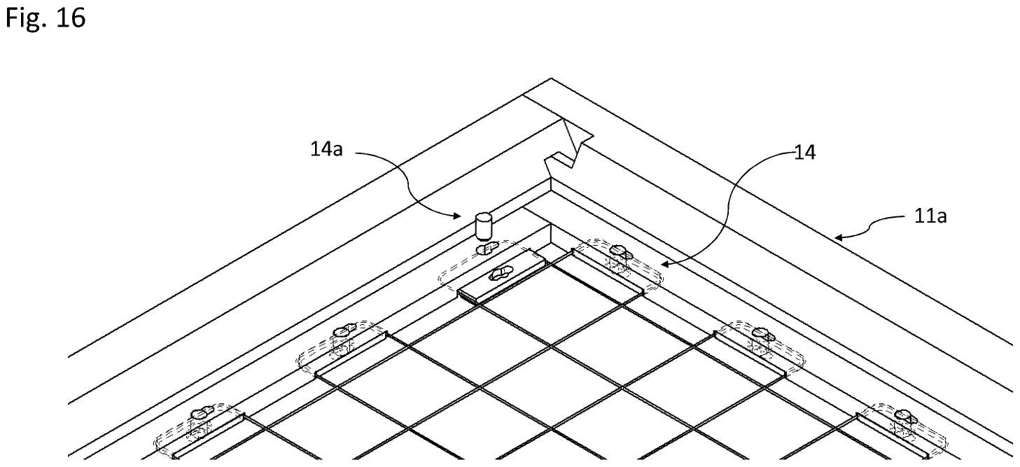

FIG. 16 shows a perspective detailed view from above of the spacer according to FIG. 13.

FIG. 1 shows a schematic sectional view through a heating system for heating large-area substrates according to a preferred embodiment of the present invention. The heating system comprises a susceptor plate 1 with an upper surface 1a and a lower surface 1b, wherein the susceptor plate 1 is preferably opaque to infrared radiation. Several spacers 2 are arranged on the upper surface 1a of the susceptor plate 1. A large-area substrate 4 is supported on the spacers 2. According to the invention, the spacers 2, which are schematically indicated here, are crossing points of a covering made of spacer elements, which covering will be explained in more detail below. Preferably, the spacers 2 consist of a material with low thermal conductivity in order to largely prevent direct thermal conduction from the susceptor plate 1 to the substrate 4.

An infrared radiation source 3 is schematically indicated below the susceptor plate 1, said infrared radiation source being configured to heat the lower surface 1b of the susceptor plate 1 by means of infrared radiation. The infrared radiation source 3 may be one individual, wide-area radiation source or an arrangement of several radiant heaters, e.g., several tubular IR radiators.

In this context, it is to be stressed that the sketch according to FIG. 1 is not true to scale. In fact, the substrate 4 may have an area of several square meters, whereas the cross-sectional area of the individual spacers or crossing points 2 is usually only a few square millimeters.

The applicant has carried out extensive experiments on different spacers, which have shown that a number of parameters are relevant for the geometry and arrangement of the spacers. As already explained above, the spacers should preferably be dimensioned in such a way that the substrate is distanced from the susceptor plate by at least 1 mm, more preferably by at least 2 mm, in order to minimize the influence of the gap size on the energy transfer. In this way, homogeneous heating can be achieved.

As already explained above, the distance between adjacent spacers also plays a role. The higher the glass substrate is heated, the lower its viscosity becomes. In the area of the glass transition temperature, the substrate material begins to flow slowly. Depending on the maximum temperature reached and the time that the substrate is supported on the spacers at this temperature, it is possible to determine the maximum distance between adjacent spacers that still leads to tolerable deformation of the substrate.

The geometry of the spacer elements has an influence on the heating of the substrate by the thermal radiation since the spacer elements shade the substrate in this respect. It is therefore also desirable that the maximum cross-sectional area or the projection of the spacer elements onto the substrate surface is as small as possible. In fact, the greatest temperature inhomogeneities during heating were determined in the area of the spacer elements in the applicant's experiments.

As explained at the outset, the invention according to one aspect is directed to a heating system for heating large-area substrates, the heating system comprising a susceptor plate with an upper surface and a lower surface, several spacers above the susceptor plate and a heating source which is arranged directly at or in the susceptor plate and configured to heat the susceptor plate directly. A preferred embodiment of this aspect of the invention can be seen schematically in FIG. 2, where a heating coil 3a extends within the susceptor plate 1. Otherwise, the preferred features discussed in the context of the other figures also apply to this embodiment.

The applicant has carried out the method according to the invention with a heating device according to the invention (with components corresponding to those described below in the context of the heating test, wherein a CFC plate with dimensions of 200 mm×200 mm×1 mm was used as the susceptor plate) and determined the temperature curves over time of the susceptor plate of the heating device and a glass substrate. FIG. 3 shows the corresponding result. FIG. 4 shows the heating rates determined from the temperature curves according to FIG. 3. As can clearly be seen, the susceptor plate is heated very rapidly by the heating device according to the invention, particularly during the first 20-30 s, wherein the corresponding heating rate passes through a maximum of greater than 25 K/s. The substrate is heated with a time delay at significantly lower heating rates: the maximum substrate heating rate, which is reached much later, is less than 5 K/s. Accordingly, very large temperature gradients form between the susceptor plate and the substrate, which ultimately ensure effective, homogeneous, and rapid heating of the substrate.

### Heating Test

A heating test is described below, which can be used to check whether the maximum heating rate ratios according to the invention can be achieved with a susceptor plate or whether the susceptor plate has the properties for electromagnetic waves, in particular IR radiation, according to the invention. The test setup shown schematically in FIG. 5 is used for this purpose.

The test setup contains four regularly arranged short-wave IR emitters (300-460 mm long), each with one or two coils and a total output of 1.5-3 kW. The round tube emitters are provided with a reflective coating of gold, aluminum oxide, or QRC™ (quartz reflective coating), where R≥50%. In FIG. 5, the IR emitters are marked with the reference sign 3. The distance between the IR emitters 3 is to be 50-55 mm.

Above the four IR emitters 3, the susceptor plate 1 to be tested is supported on two symmetrically positioned tubes 7 such that the distance between the susceptor plate 1 and the IR emitters 3 is also 50-55 mm. Ceramic tubes made of aluminum oxide 10×1 or quartz tubes 10×1 (with a length of 300-500 mm) can be used for this purpose. The tubes 7 run perpendicular to the IR emitters 3 and are 90-100 mm apart. If the susceptor plate to be tested is larger than 200 mm×200 mm (+20/−5), the plate is cut to this size and a plate section of 200 mm×200 mm (+20/−5) is measured.

A thermocouple TC1 is attached to the upper surface of the susceptor plate 1 as centrally as possible using a high-temperature adhesive such as, e.g., silver paint (cf. FIG. 6).

The reference substrate for the heating test is a glass substrate made of clear float glass with a softening temperature of 510-650° C. and an area of 100 (+10/−5) mm×100 (+10/−5) mm and a thickness of 2 (+/−0.2) mm.

With respect to the susceptor plate 1, the reference substrate 4 is placed as centrally as possible on four spacers 2 which are placed at the four corners of the reference substrate 4 (cf. FIG. 5). The spacers 2 are made of ceramic with a height of 2-3 mm and a diameter of 8-10 mm.

A thermocouple TC2 is attached to the upper surface of the reference substrate as centrally as possible using a high-temperature adhesive such as, e.g., silver paint (cf. FIG. 7). For thermocouples TC1 and TC2, e.g., a type K sheathed thermocouple with sheath material 1.4541 or 2.4816 and a sheath diameter of 0.5 (+/−0.2) mm can be used.

The heating test is carried out in a closed room under a nitrogen atmosphere at 1,000 (+/−100) hPa, an partial oxygen pressure of at most 10 ppm and a water dew point of at most −40° C. The test is started at room temperature, i.e., 23 (+/−3° C.)

When t=0 s, the four IR emitters are switched on simultaneously with a power of 1.5 kW each (corresponding to a total radiation power of 6 kW) and the susceptor plate is heated with constant radiation power until a temperature greater than or equal to 600° C. is measured on the reference substrate using the thermocouple TC2. The IR emitters are then switched off.

During the heating process, a temperature at the susceptor plate is measured for a total of 90 s every full second (i.e., for t=1 s, t=2 s, . . . , t=90 s) using the thermocouple TC1 and a temperature at the reference substrate is measured using the thermocouple TC2. From these measured temperatures, a heating rate for the susceptor plate and the reference substrate is determined for each full second by calculating the difference quotient (e.g., heating rate for the susceptor plate for t=1 s: (T_{TC1} (t=1 s)−T_{TC1} (t=0 s))/1 s.

According to the invention, the maximum heating rate of the susceptor plate during the first 20 s of heating is understood to be the maximum of the 20 values thus determined for the susceptor plate. According to the invention, the maximum heating rate of the reference substrate during the first 20 s of heating is understood to be the maximum of the 20 values thus determined for the reference substrate.

According to the invention, the maximum temperature difference between the susceptor plate and the reference substrate during the first 90 s of heating is understood to be the maximum difference between the differences determined at the 90 times between the temperatures determined in each case for the susceptor plate and the reference substrate.

FIGS. 8a and 8b show a preferred embodiment of a spacer device according to the invention for a heating system for heating large-area substrates in a perspective view in the assembled (FIG. 8a) and disassembled (FIG. 8b) states. The spacer device 10 has a frame 11 and a covering 13 supported by the frame 11 and consisting of several intersecting flexible spacer elements. In the preferred embodiment shown, the frame 11 is essentially formed from four frame members 11a of equal length, which form a square frame structure. At the four corners of the spacer device 10, the four frame members 11a are connected to each other with the aid of connecting members 12. These connecting members 12 preferably project upwards from the frame 11, thus forming boundary or guide sections in order to support a substrate to be heated centrally on the spacer device 10.

In the preferred embodiment shown, the covering 13 supported by the frame 11 consists of a woven structure with 20 spacer elements running in the longitudinal direction and 20 spacer elements running in the transverse direction, which form 414 square meshes and 400 crossing points in a square pattern.

As a matter of course, these details are merely exemplary features. For instance, the frame 11 does not have to be square but can also have a rectangular or other shape. Furthermore, more or fewer spacer elements can be mounted on the frame in the same or a different pattern. However, with regard to homogeneous support of the substrate, it is preferred that the spacer elements define a regular pattern of intersections, thus forming a pattern of spacers which are substantially equidistant from each other.

In order to form supporting points for the substrate that are as punctual as possible, it is preferred that the intersecting spacer elements form a woven structure in which each transverse element is guided alternately above and below a longitudinal element and vice versa, as schematically indicated in FIG. 10.

Preferably, the frame 11 comprises several deflection elements 14 (cf. FIG. 9) to accommodate the covering 13. In the preferred embodiment shown according to FIGS. 8-12, the frame can be disassembled for covering the frame. In the preferred embodiment shown, this is achieved by the frame members 11a each having dovetail-shaped sections 15 at their ends (see FIG. 9) which can engage with corresponding recesses in the connecting members 12 (see FIG. 11). The frame may therefore be disassembled and reassembled in a few simple steps.

In order to make the formation of the covering as simple as possible in this embodiment, the deflection elements 14 are T-shaped. In the disassembled state of the frame 11 shown in FIG. 9, the individual frame members 11a are rotated by 90° around their respective longitudinal axis compared to the assembled position so that the deflection elements 14 point upwards. In this state, a long piece of cord of a spacer element can be easily placed around a deflection element 14 of a first frame member 11a, guided over and under the corresponding transverse elements to the opposite frame member and placed there again around a corresponding deflection element 14. Ideally, the complete covering can be formed with one single piece of cord, e.g., by first tensioning all the longitudinal elements starting at one corner of the frame 11 and then guiding all the transverse elements above or below the longitudinal elements and tensioning them as well.

If the covering has been formed in this (or another) way, the frame members 11a are each turned inwards by 90° around their respective longitudinal axis so that the deflection elements 14 then point inwards, as can be seen in FIG. 10. The frame members 11a are then connected to each other by means of the connecting elements 12 to form the assembled frame 11. In the assembled frame 11, the spacer elements then run essentially within a plane defined by the lower edge of the frame, as can be seen in FIG. 10. If the spacer device 10 is then placed on, e.g., a susceptor plate, the spacer elements of the covering 13 are in direct contact with the susceptor plate, at least at the intersection points. A substrate that is then supported on the spacer device 10 will rest on these crossing points accordingly and be held at a well-defined distance from the susceptor plate by the crossing points of the covering.

As can be seen from the preferred embodiments according to FIGS. 8 to 12, the entire spacer device and, in particular, its frame can be designed to be very narrow so that the spacer device hardly takes up any space above the susceptor plate and leaves space for further elements that may be required during the heating process. Preferably, the thickness or height of the frame of the spacer device (including the deflection elements) is less than 15 mm, more preferably less than 12 mm, and particularly preferably less than 10 mm.

The deflection elements are preferably made of the same material as the frame members of the frame and are preferably manufactured integrally with the latter. Furthermore, the deflection elements preferably have a slightly smaller thickness or height than the frame members of the frame.

However, the deflection elements 14 may also be detachably arranged on the frame 11, as shown by way of example for the embodiment according to FIGS. 13 to 16. In this embodiment, the deflection elements 14 for covering the frame 11 can be disassembled, whereas the frame itself is not disassembled when the covering is replaced. It is thus possible to mount the frame of the spacer device on the susceptor plate or even to fix it permanently thereto.

In the preferred embodiment according to FIGS. 13 to 16, the deflection elements 14 are configured as mounting links (cf. FIGS. 14 to 16) which can be mounted to the frame members 11a of the frame 11 by means of, e.g., bolts 14a. Instead of bolts, other mounting mechanisms can of course also be provided. For instance, the mounting links 14 can be clipped into corresponding recesses or attached to corresponding pins.

In principle, this frame 11 could be covered with the deflection elements 14 in the fully assembled state, for example by placing a spacer element cord around the corresponding mounting links 14, thus weaving the tension. However, in order to make the covering as simple as possible, it is advantageous to remove the mounting links 14 from the frame 11, form the weaving pattern of the spacer elements together with the detached mounting links 14 and then attach the mounting links together with the covering to the frame elements 11a.

In the embodiment according to FIGS. 13 to 16 shown here, the frame 11 is significantly thicker, i.e., higher than in the case of the previously discussed embodiment. As a matter of course, the frame may be produced with the above-mentioned preferred dimensions in the present embodiment as well. However, since in the embodiment according to FIGS. 13 to 16 the spacer device 10 as a whole is preferably mounted on the susceptor plate and does not have to be disassembled to replace the covering, it is advantageous in this embodiment to provide a higher frame in which further components required in the context of the heating process, such as nozzles or the like, can be arranged, if necessary.

1. A spacer device for a heating system for heating large-area substrates, wherein the spacer device comprises:
a frame; and
a covering supported by the frame and made of several intersecting flexible spacer elements.

2. The spacer device according to claim 1, wherein the intersecting spacer elements form a woven structure.

3. The spacer device according to claim 1, wherein the spacer elements have an E modulus of at most 75 GPa.

4. The spacer device according to claim 1, wherein the fill factor of the spacer elements is at least 50%.

5. The spacer device according to claim 1, wherein the spacer elements are formed from string, cord, braided hose, and/or threads.

6. The spacer device according to claim 1, wherein the spacer elements comprise quartz, glass, glass fiber composite and/or carbon composite.

7. The spacer device according to claim 1, wherein the spacer elements comprise a diameter of between 0.3 and 3.0 mm.

8. The spacer device according to claim 1, wherein the frame is rectangular and the covering comprises longitudinal and transverse elements which extend parallel to the frame members.

9. The spacer device according to claim 1, wherein the covering comprises a mesh size between adjacent spacer elements of between 10 and 150 mm.

10. The spacer device according to claim 1, wherein the frame is made of graphite and/or carbon fiber carbon composite.

11. The spacer device according to claim 1, wherein the frame comprises several deflection elements around which the covering is guided.

12. The spacer device according to claim 11, wherein the deflection elements are demountable for covering the frame.

13. The spacer device according to claim 11, wherein the frame is demountable for covering the frame.

14. A heating system for heating large-area substrates, the heating system comprising:
a susceptor plate with an upper surface and a lower surface, wherein the susceptor plate is opaque to infrared radiation;
a spacer device according to claim 1 which is arranged above the susceptor plate; and
an infrared radiation source which is arranged and configured to heat the lower surface of the susceptor device by means of infrared radiation.

15. A heating system for heating large-area substrates, the heating system comprising:
a susceptor plate with an upper surface and a lower surface;
a spacer device according to claim 1 which is arranged above the susceptor plate; and
a heating source which is directly arranged at or in the susceptor plate and configured to heat the susceptor plate directly.

16. The heating system according to claim 14, wherein the thermal conductivity of the spacer elements in the direction perpendicular to the plane defined by the susceptor plate is less than 15 W/(m·K).

17. The heating system according to claim 14, wherein the susceptor plate comprises a transmission of less than 10% for infrared radiation in the entire wavelength range between 0.5 μm and 10.0 μm.

18. (canceled)

19. The spacer device according to claim 5, wherein several or all spacer elements are formed from one single string and/or one single cord and/or one single braided hose.

20. The spacer device according to claim 14, wherein the deflection elements are T-shaped.
